(19) United States
(12) Patent Application Publication
(10) Pub. No.: US 2012/0069518 A1
(43) Pub. Date: Mar. 22, 2012

(54) PORTABLE ELECTRONIC DEVICE

(76) Inventors: Hsin-An HSU, Taipei City (TW); Jin-De Lin, Taipei City (TW); Yi-Hsiang Chao, Taipei City (TW)

(21) Appl. No.: 13/033,841

(22) Filed: Feb. 24, 2011

(30) Foreign Application Priority Data
Sep. 21, 2010 (TW) 099131975

(51) Int. Cl. H05K 5/02

(52) U.S. Cl. 361/679.58

(57) ABSTRACT

A portable electronic device includes a computer housing and a cover, wherein the computer housing includes a housing side portion and a housing surface portion neighboring to the housing side portion, an accommodating recess, a pivot slide recess, and a hook slide recess. The cover includes a cover body, a pivoting portion and a hook portion. The housing side portion and the housing surface portion are recessed together so as to define the accommodating recess. The accommodating recess is provided with two positioning areas and a socket area in connection with the two positioning areas, and that the socket area is provided with an extension socket. The cover body covers, selectively, the accommodating recess, and that the pivoting portion can slide and can be pivotally arranged in the pivot slide recess, while the hook portion can slide and can be arranged in the hook slide recess.

### BACKGROUND OF THE INVENTION

1. Field of the Invention

The present invention relates to a housing structure for an electronic device, and more particularly, to a housing structure adapted for a portable electronic device.

2. Description of Related Art

Nowadays, portable electronic devices, such as flat-panel computers, notebook computers, personal digital assistants, and so forth, are normally provided with extension sockets, for being connected with externally-connected extension units, in response to a possibility of extension in the future. To comply with various interface specifications, currently exist in the market a variety of sockets for options.

For example, universal serial bus (USB) is one of the serial port bus standards for connecting with externally-connected extension devices, and has been widely employed for computers such that data exchange can be speedy, driver software is not required, and hot swapping can be realized. In other words, when in use for data storage, only plugging USB adapters to USB sockets in computers or other electronic facilities is required, and thus it is convenient for portability.

USB-connection devices, including drives, TV sticks, wireless cards or wireless modules such as 3G Dongles, have been very popular, to the effect, the drives can be used for data storage and exchange, while the wireless modules for proceeding with digital transmission and receiving. Generally speaking, a USB-connection device is equipped with a USB adapter for plugging to a USB extension socket in a computer mainframe, a flat-panel computer, a notebook computer, or in an adapter. Referring to FIG. 1, a schematic view illustrating a conventional flat-panel computer, a USB extension socket 93 is provided at a side 92 of a computer housing 91. Whenever a user intends to connect a USB drive 94 with a flat-panel computer 90, a USB adapter 941 is employed to align with the USB extension socket 93 and to plug into the USB extension socket 93 directly so as to establish an electrical connection therewith.

Obviously, under the above-mentioned structure, plugging the USB drive 94 to the flat-panel computer 90 runs a potential risk. This is because the USB drive 94 protrudes, alone, from the side 92 of the computer housing 91, and the length protruded from the side 92 of the computer housing 91 is equal to the length of a USB housing 942. People around the flat-panel computer 90 will easily impact the USB drive 94, unintentionally, and as a result, this causes damage thereto.

### SUMMARY OF THE INVENTION

An object of the present invention is to provide a portable electronic device, which, while being plugged into portable electronic devices such as a flat-panel computer and so forth, an externally-connected extension device, the externally-connected extension device can be concealed, so that the possibility of loosening off or damage thereof can be avoided when the externally-connected extension device is hit.

To achieve the object, the portable electronic device, according to the present invention, comprises a computer housing and a cover, wherein the computer housing includes a housing side portion and a housing surface portion neighboring to the housing side portion. The computer housing further includes an accommodating recess, a pivot slide recess, and a hook slide recess, wherein the housing side portion and the housing surface portion are recessed together for certain areas so as to define the accommodating recess.

According to the present invention, the accommodating recess is provided with two positioning areas and a socket area in connection with the two positioning areas, wherein the socket area is provided with an extension socket opened to, and away from, a housing-side opening.

The cover includes a cover body, a pivoting portion, and a hook portion, where the pivoting portion and the hook portion extend from the cover body, respectively. The cover body can cover, selectively, the accommodating recess at top of the housing surface portion. The pivoting portion can slide and can be pivotally arranged in the pivot slide recess, while the hook portion can slide and can be arranged in the hook slide recess.

In view of the above-mentioned structural design, it is understood that not only can the cover serve the function of dust-proof and protection of the externally-connected extension device, but also can the externally-connected extension device, which has a certain length, be concealed for most part thereof when it is plugged to a body of the portable electronic device. Therefore, aside from a desirable appearance, the externally-connected extension device will not be protruded too much from the portable electronic device so as to avoid from being subject to impact and leading to loosening off or damage of the externally-connected extension device.

According to the present invention, at least one of the two positioning areas is protruded with a baffling-positioned element which is arranged in an extendible manner. In addition, the accommodating recess further includes a bottom wall in connection with the two positioning areas, wherein a baffling-positioned element can also be protruded from the bottom wall. Or even a baffling-positioned element can be protruded from inner side of the cover. These baffling-positioned elements not only provide the function of stable holding when the externally-connected extension device is plugged to the portable electronic device, but also play a key role in fitting externally-connected extension devices of various dimensions.

According to the present invention, the configurations of the baffling-positioned elements are not to be limited. For example, the baffling-positioned elements may consist of two metal elastic sheets located at the positioning areas, respectively, and opposite to each other. The metal elastic sheets may each be provided with an arc positioning surface for holding and positioning the externally-connected extension device, so that a smooth plugging process for the externally-connected extension device to the portable electronic device can be obtained. Further, the baffling-positioned elements may be plural elastic rubber strips, or an elastic rubber layer having a [symbol] -shape cross-section and covering on the bottom wall and the positioning areas. The baffling-positioned elements may also be a combination of metal balls and springs such that the externally-connected extension device can be held by the metal balls and the compressed springs at two sides thereof.

Further, according to the present invention, the pivot slide recess may be provided with a neck portion, so that the cover can be positioned, at stages, in a pivoted or in a not pivoted status.

Still further, the portable electronic device may further include an extended connecting element having an extension adapter and an extension port, where the extension adapter can be removable and can be plugged into the extension socket, and the extension port is exposed out of the accommodating recess. This will facilitate an externally-connected extension device, which has a length less than that of the accommodating recess, to be plugged into the portable electronic device so as to avoid the difficulty of plugging carried out in the accommodating recess.

Other objects, advantages, and novel features of the present invention will become more apparent from the following detailed descriptions when taken in conjunction with the accompanying drawings.

### BRIEF DESCRIPTION OF THE DRAWINGS

FIG. 1 is a schematic view illustrating a conventional flat-panel computer;

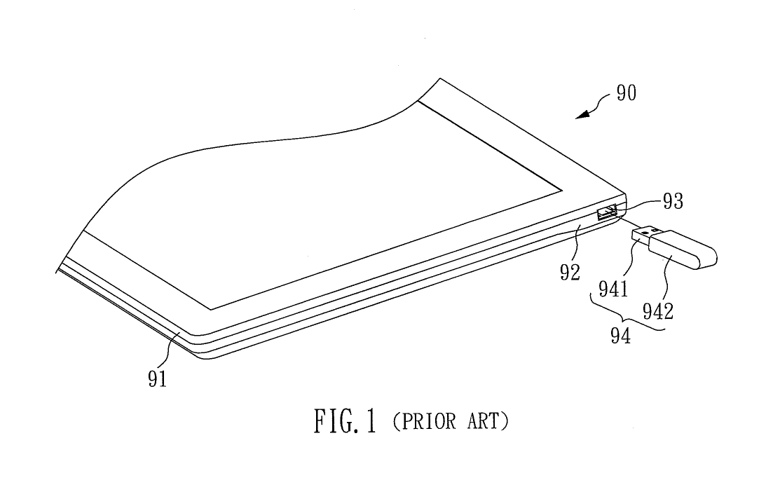

FIG. 2 is an exploded view illustrating part of a portable electronic device according to a first embodiment of the present invention;

FIG. 3 is a perspective view illustrating a cover of the portable electronic device, shown in FIG. 2, having not been pivoted yet;

FIG. 4 is a perspective view illustrating the cover of the portable electronic device, shown in FIG. 2, having been pivoted already;

FIG. 5 is a perspective view illustrating the portable electronic device, as shown in FIG. 2, being in connection with an externally-connected extension device;

FIG. 6A is a cross-sectional view illustrating the cover of the portable electronic device, shown in FIG. 2, being refrained from opening;

FIG. 6B is a cross-sectional view illustrating the cover of the portable electronic device, shown in FIG. 2, being free for opening;

FIG. 7 is a perspective view illustrating part of a portable electronic device according to a second embodiment of the present invention;

FIG. 8 is a perspective view illustrating part of a portable electronic device according to a third embodiment of the present invention;

FIG. 9 is a cross-sectional view illustrating part of a portable electronic device according to a fourth embodiment of the present invention;

FIG. 10 is an exploded view illustrating part of a portable electronic device according to a fifth embodiment of the present invention;

FIG. 11 is a perspective view illustrating part of the portable electronic device according to the fifth embodiment of the present invention; and

FIG. 12 is a perspective view illustrating part of the portable electronic device, as shown in FIG. 10, being in connection with an externally-connected extension device.

### DETAILED DESCRIPTION OF THE PREFERRED EMBODIMENTS

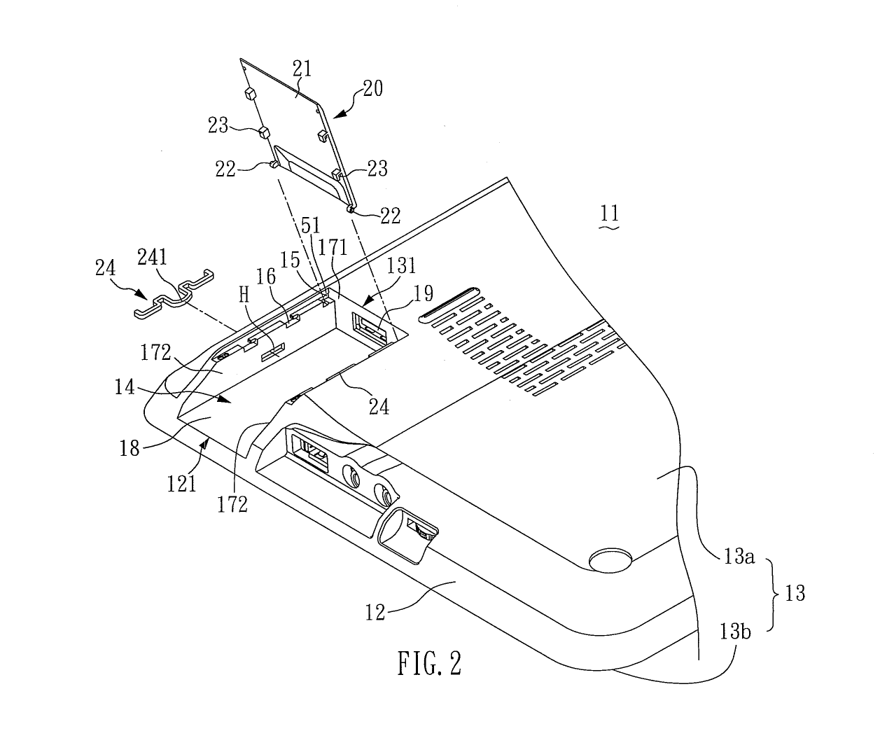

Referring to FIG. 2, an exploded view illustrating part of a portable electronic device according to a first embodiment of the present invention, where the housing of a flat-panel computer is shown, the computer housing 11 includes a housing surface portion 13 and a housing side portion 12. The housing surface portion 13 includes a top surface 13b and a bottom surface 13a neighboring to the housing side portion 12, respectively. In the present embodiment, the top surface 13b is arranged with a screen and/or a touch panel (not shown), while the bottom surface 13a and the housing side portion 12 are recessed together for certain areas so as to define an accommodating recess 14.

In the present embodiment, in addition to the accommodating recess 14, the computer housing 11 is also provided with a pivot slide recesses 15 and a hook slide recesses 16, wherein the pivot slide recess 15 is defined by a restricting block 51 neighboring to a housing-surface opening 131 and extending toward one side of the computer housing 11. The housing-surface opening 131 is referred to as the area at the accommodating recess 14 at the top of the bottom surface 13a of the computer housing 11; whereas a housing-side opening 121 is referred to as the area at the accommodating recess 14 at one side of the housing side portion 12. The accommodating recess 14 includes a side-wall portion and a bottom-wall portion 18, wherein the bottom-wall portion 18 neighbors to a lower portion of the side-wall portion. The side-wall portion includes two positioning areas 172 and a socket area 171 in connection with the two positioning areas 172. The two positioning areas 172 and the socket area 171 constitute, together, a [symbol] -shape profile. The socket area 171 is provided with an extension socket 19 which is opened to the housing-side opening 121.

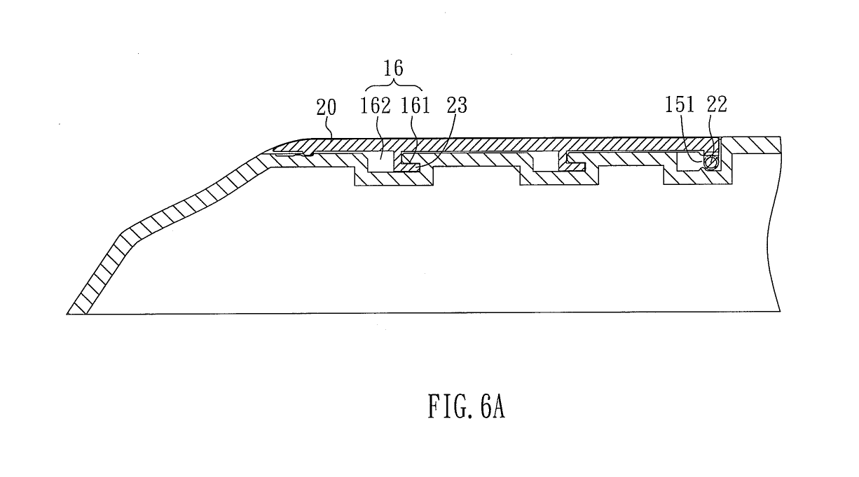

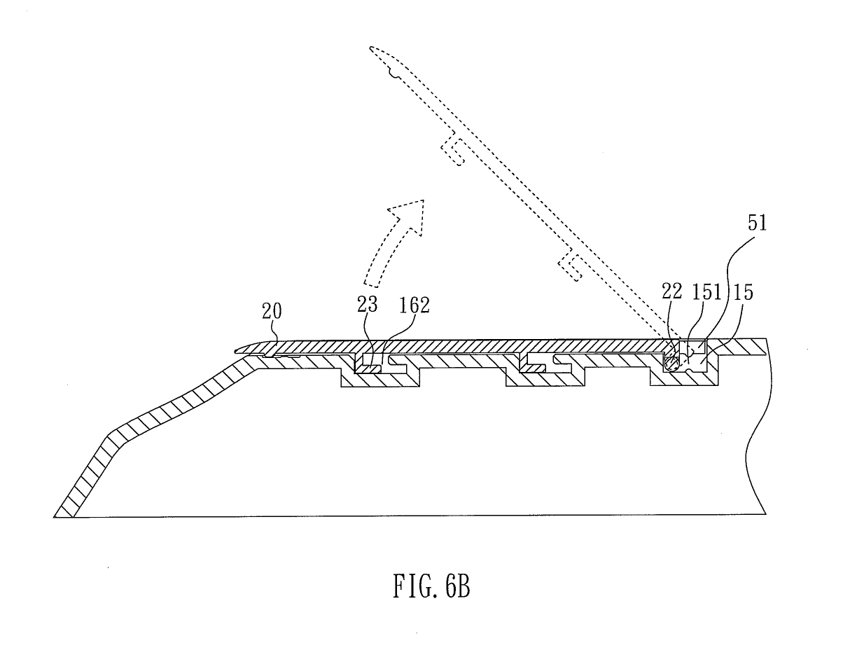

The extension socket 19 and the housing-side opening 121 are apart from each other at a predetermined distance for receiving most part of the length of an extension device. Now referring to FIG. 6A, a cross-sectional view illustrating a cover of the portable electronic device being refrained from opening, and also to FIG. 2, the pivot slide recess 15 includes a neck portion 151 located between the front and rear ends thereof. The hook slide recess 16 is provided at top of the positioning area 172, and includes a restricting section 161 and a free section 162 which are connected with each other, wherein the free section 162 is communicated, directly, with the housing-surface opening 131.

In the present embodiment, the cover 20 includes a cover body 21, a pivoting portion 22, and a hook portion 23, where the pivoting portion 22 and the hook portion 23 extend outward, respectively, from the cover body 21. The pivoting portion 22 is shaped as a short cylinder, and it can slide and can be pivotally arranged in the pivot slide recess 15, while the hook portion 23 can slide and can be arranged in the hook slide recess 16. Depending on sliding of the pivoting portion 22 and the hook portion 23 in the pivot slide recesses 15 and the hook slide recesses 16, respectively, the cover body 21 can cover, selectively, the housing-surface opening 131.

The two positioning areas 172 at side walls of the accommodating recess 14 are each protruded with a baffling-positioned element 24 arranged opposite to each other. In the present embodiment, the baffling-positioned elements 24 are each formed with metal elastic sheets, part of which is concealed within, and abutting against, the computer housing 11, and part of which extends out of a hole H of the positioning area 172 and into the accommodating recess 14. Particularly, the metal elastic sheets are each provided with an arc positioning surface 241, so that the extension device can contact with the metal elastic sheets at a smoother manner, and that frictional obstacles and damages can be reduced.

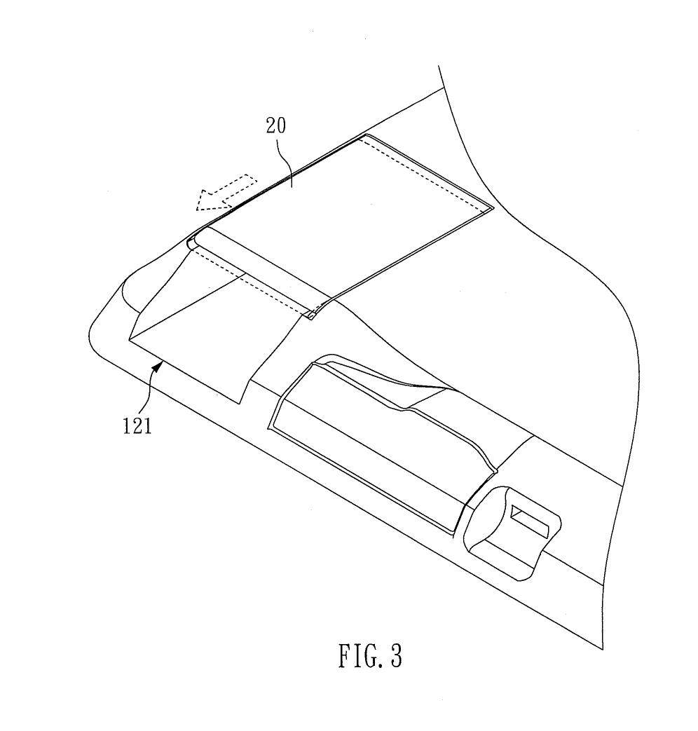

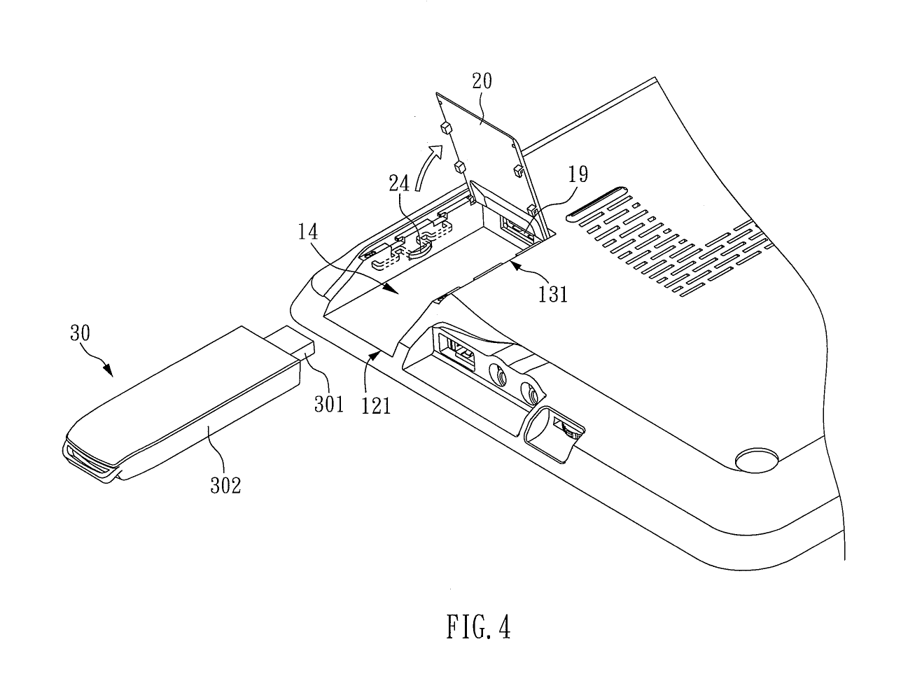

A process of use of the portable electronic device is exemplified with the following description, namely, FIGS. 3 and 4 are perspective views illustrating the cover of the portable electronic device at different positions; and FIGS. 6A and 6B are cross-sectional views illustrating the cover at different positions.

First referring to FIGS. 3 and 6A, when none of any externally-connected extension devices is connected with the flat-panel computer, the cover 20 covers the housing-surface opening, as shown in FIG. 3 presented by solid lines. At this moment, the pivoting portion 22 of the cover 20 is located in a space at right side of the neck portion 151, and that the hook portion 23 of the cover 20 is restricted at the restricting section 161 of the hook slide recess 16, so that the cover 20 cannot be pivoted upward.

As shown in FIG. 3 and FIG. 6B, when a user intends to plug the externally-connected extension devices to the flat-panel computer, the cover 20 is first drawn toward the housing-side opening 121, as shown in FIG. 3 presented by dotted lines. At this moment, the pivoting portion 22 of the cover 20 slides across the neck portion 151 and reaches to the left side of the neck portion 151, while the hook portion 23 of the cover 20 slides to the free section 162 of the hook slide recess 16, as shown in FIG. 6B presented by solid lines. Thereafter, because the hook portion 23 is no longer restricted, and because the pivoting portion 22 of the pivot slide recess 15 can be pivoted, the cover 20 can be opened and pivoted upward, as shown in FIG. 6 B presented by dotted lines. In addition, since the pivoting portion 22 is restricted by the restricting block 51, the cover 20 will not move upward and out of the computer housing 11.

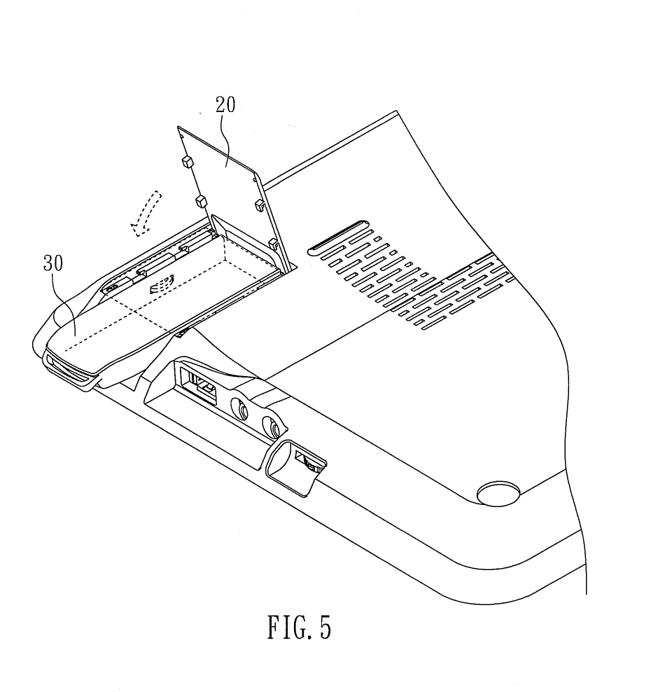

Now referring to FIGS. 4 and 5, when the cover 20 is released from covering the housing-surface opening 131, the user can plug an adapter 301 of an externally-connected extension device (such as an USB drive) 30 into the housing-side opening 121 till being engaged with the extension socket 19. Because the user can observe an actual engaging status of the externally-connected extension device 30 through what is exposed from the housing-surface opening 131, a complete connection between the externally-connected extension device 30 and the flat-panel computer can, therefore, be assured. In addition, since the accommodating recess 14, which has a certain length and able to receive most part of the externally-connected extension device 30 or even all of a casing portion 302 of the externally-connected extension device 30 (depending on the specification of the externally-connected extension device 30), possibilities of adverse effect resulted from loosening off or damage of the externally-connected extension device 30, which is in a state of connection, due to impact, can be reduced.

On the other hand, the baffling-positioned elements 24 at the side walls of the accommodating recess 14 can be stretchable, in compliance with the width of the casing portion 302 of the externally-connected extension device 30, and hold the externally-connected extension device 30 in position. This will assure a safety usage of the externally-connected extension device 30. In other words, provision of the baffling-positioned elements 24 can help the portable electronic device fit externally-connected extension devices 30 of various dimensions.

After firmly connecting the externally-connected extension device 30 with the flat-panel computer, the cover 20 can be operated in a reverse order different from the above so as to cover and protect the externally-connected extension device 30.

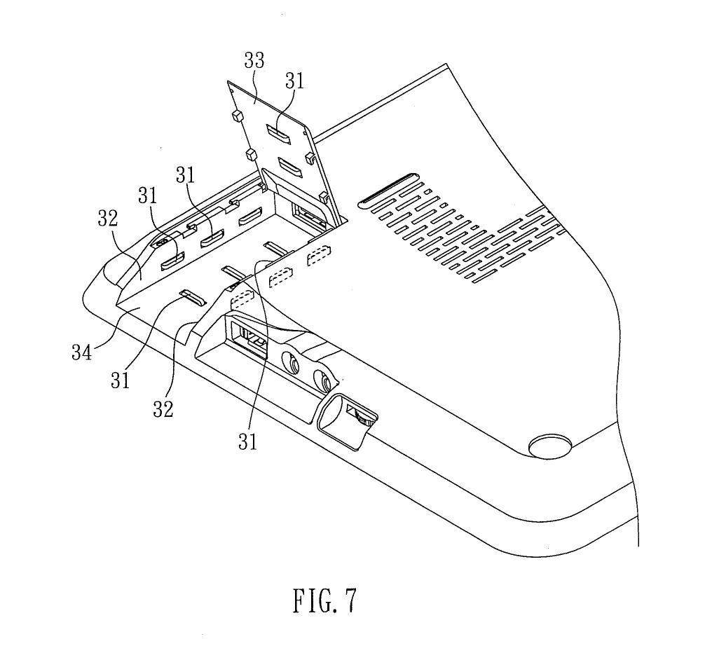

Further referring to FIG. 7, a perspective view illustrating part of a portable electronic device according to a second embodiment of the present invention, the second embodiment is substantially similar to the first embodiment in terms of structure, except that in the former there are provided with elastic rubber strips 31 acting as baffling-positioned elements, where the elastic rubber strips 31 are provided at two positioning areas 32, a cover inner side 33, and an accommodating bottom wall 34. This will also achieve the purpose, as the first embodiment, that the elastic rubber strips 31 can help the portable electronic device fit and position externally-connected extension devices 30 of various dimensions.

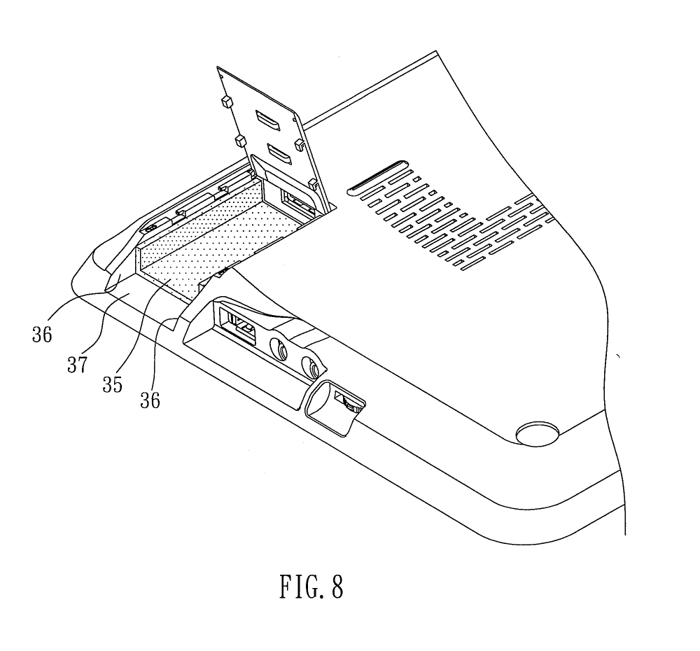

Now referring to FIG. 8, a perspective view illustrating part of a portable electronic device according to a third embodiment of the present invention, the present embodiment has a structure substantially similar to that of the first embodiment, with the exception that in the present embodiment a baffling-positioned element 35, being an elastic rubber layer and having a [symbol] -shape cross-section, covers two positioning areas 36 and a bottom wall 37. Similarly, the baffling-positioned elements 35 can also achieve the purpose of fitting and positioning externally-connected extension devices 30 of various dimensions.

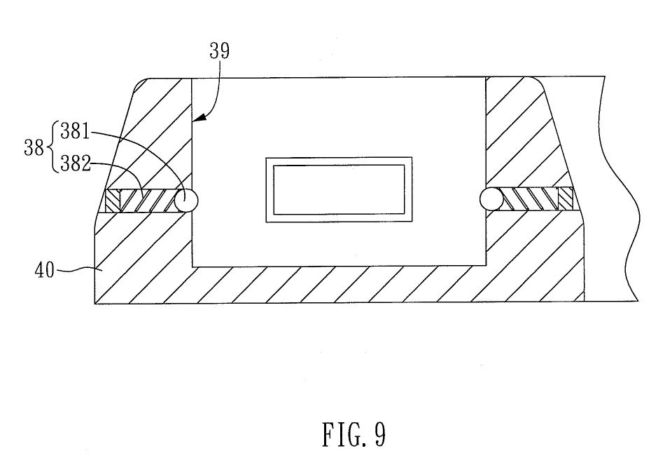

Reference is made to FIG. 9, a cross-sectional view illustrating part of a portable electronic device according to a fourth embodiment of the present invention. This embodiment is also substantially similar to the first embodiment, except that in the fourth embodiment two baffling-positioned elements 38 each consists of a ball 381 and a spring 382, wherein the spring 382 biases, at one end, against a computer housing 40, and at the other, the ball 381. The spring 382 pushes the ball 381 to expose out of a positioning area 39 for a certain part. Likewise, the baffling-positioned elements 38 can also achieve the purpose of fitting and positioning externally-connected extension devices 30 of various dimensions.

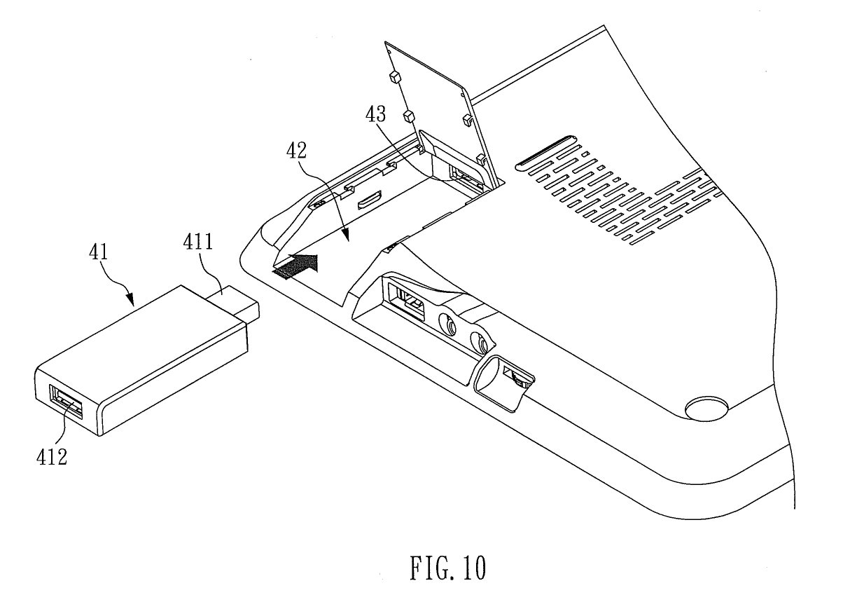

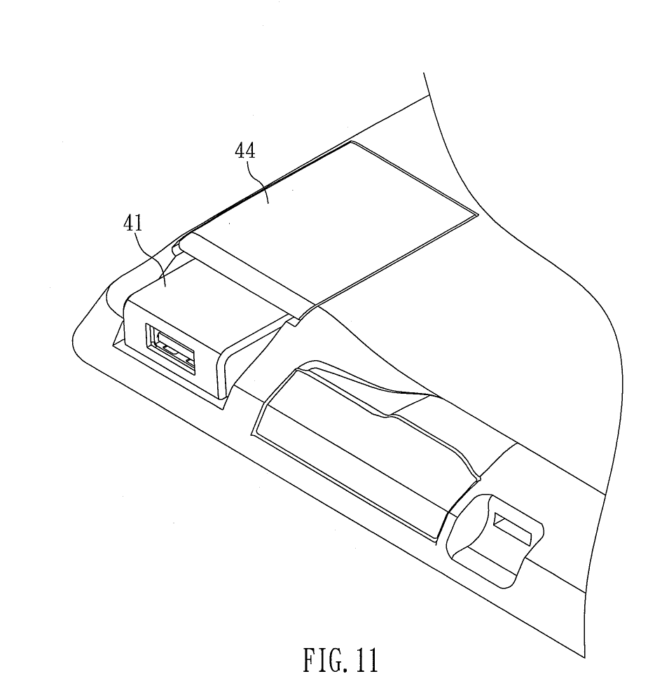

Still further, referring to FIGS. 10 and 11, exploded and perspective views illustrating part of a portable electronic device according to a fifth embodiment of the present invention, the fifth embodiment is substantially similar to the first embodiment as far as the structure is concerned, except that in the fifth embodiment an extended connecting element 41 is additionally provided, where the extended connecting element 41 has an extension adapter 411 and an extension port 412, and where the extension adapter 411 is plugged into an extension socket 43 and the extension port 412 exposed out of an accommodating recess 42. In particular, the extended connecting element 41 can be removed as desired. FIG. 11 shows that the extended connecting element 41 has plugged in position, and that a cover 44 has been in a shielding state.

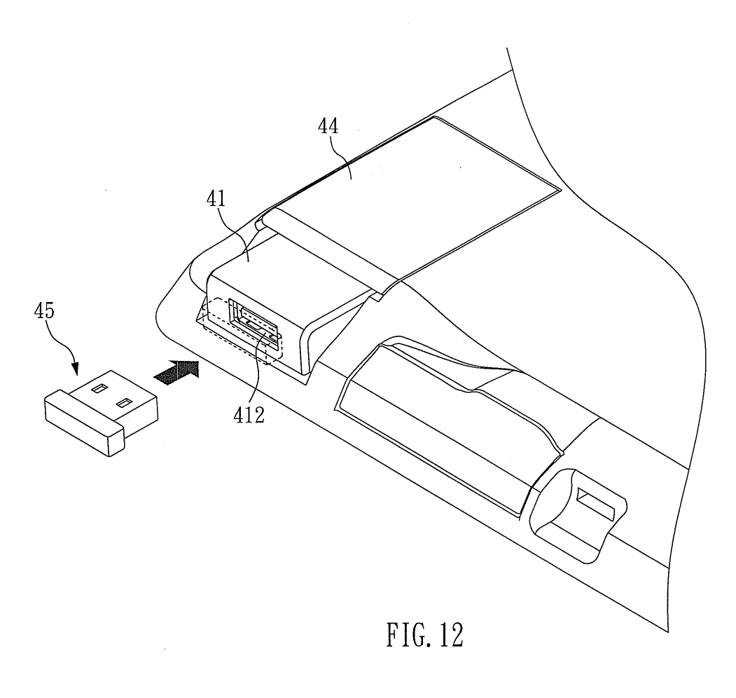

Now referring to FIG. 12, a perspective view illustrating part of the portable electronic device, as shown in FIG. 10, being in connection with an externally-connected extension device, this embodiment is suitable for an occasion when the externally-connected extension device 45, such as a blue-tooth transmission module, has a length less than that of the accommodating recess 42. This is because a shorter externally-connected extension device 45 is often used, and it will be very inconvenient if in each use the cover 44 needs to be opened. Furthermore, since the width of the accommodating recess 42 is narrow relative to the user's hand, it will be difficult to plug the externally-connected extension device 45 in position. Accordingly, to plug the shorter externally-connected extension device 45 into the extension port 412 of the extended connecting element 41 directly becomes very convenient as far as plug-in and -out of the externally-connected extension device 45 is concerned.

Although the present invention has been explained in relation to its preferred embodiments, it is to be understood that many other possible modifications and variations can be made without departing from the scope of the invention as hereinafter claimed.

What is claimed is:

1. A portable electronic device, comprising:
A computer housing, including a housing side portion, a housing surface portion neighboring to the housing side portion, an accommodating recess, a pivot slide recess, and a hook slide recess, wherein the housing side portion and the housing surface portion are recessed together to define the accommodating recess, and wherein the accommodating recess is provided with two positioning areas and a socket area in connection with the two positioning areas, and the socket area is provided with an extension socket; and
a cover, including a cover body, and a pivoting portion and a hook portion respectively extended from the cover body, wherein the cover body covers, selectively, the accommodating recess at top of the housing surface portion, and the pivoting portion can slide and can be pivotally arranged in the pivot slide recess, while the hook portion can slide and can be arranged in the hook slide recess.

2. The portable electronic device as claimed in claim 1, wherein at least one of the two positioning areas is protruded with a baffling-positioned element.

3. The portable electronic device as claimed in claim 2, wherein the baffling-positioned element includes two metal elastic sheets and are located at the positioning areas, respectively, and opposite to each other.

4. The portable electronic device as claimed in claim 3, wherein the metal elastic sheets are each provided with an arc positioning surface.

5. The portable electronic device as claimed in claim 2, wherein the baffling-positioned element includes plural elastic rubber strips.

6. The portable electronic device as claimed in claim 1, wherein the accommodating recess further includes a bottom wall adjacent to the two positioning areas, and a baffling-positioned element is protruded from the bottom wall.

7. The portable electronic device as claimed in claim 6, wherein the baffling-positioned element is an elastic rubber layer having a [symbol] -shape cross-section.

8. The portable electronic device as claimed in claim 1, wherein a baffling-positioned element is protruded from inner side of the cover.

9. The portable electronic device as claimed in claim 1, wherein the pivot slide recess is provided with a neck portion.

10. The portable electronic device as claimed in claim 1, further includes an extended connecting element having an extension adapter and an extension port, where the extension adapter can be removable and can be plugged into the extension socket, and the extension port is exposed out of the accommodating recess.
